(19) United States
(12) Patent Application Publication
(10) Pub. No.: US 2022/0375892 A1
(43) Pub. Date: Nov. 24, 2022

(54) CHIP PACKAGING METHOD AND CHIP PACKAGING STRUCTURE

(71) Applicant: Institute of Semiconductors, Guangdong Academy of Sciences, Guangdong (CN)

(72) Inventors: Yinhua CUI, Guangdong (CN); Yao WANG, Guangdong (CN); Yunzhi LING, Guangdong (CN); Wei ZHAO, Guangdong (CN); Zhitao CHEN, Guangdong (CN); Chuan HU, Guangdong (CN)

(73) Assignee: Institute of Semiconductors, Guangdong Academy of Sciences, Guangdong (CN)

(21) Appl. No.: 17/438,528

(22) PCT Filed: May 21, 2021
(86) PCT No.: PCT/CN2021/095181

§ 371 Date: Sep. 13, 2021

(51) Int. Cl. H01L 23/00; H01L 23/10

(52) U.S. Cl. CPC H01L 24/73; H01L 24/32; H01L 24/48; H01L 23/10; H01L 2224/73265; H01L 2224/325; H01L 2224/32104; H01L 2224/48135

(57) ABSTRACT

A chip packaging method and a chip packaging structure is disclosed. The method includes: attaching at least two chips to one side of substrate by adhesive layer, wherein device surface of the chip faces the substrate, and the substrate is provided therein with substrate wiring structure and/or chip; performing thinning treatment on the at least two chips provided on one side of the substrate, wherein the thinning treatment includes etching only the chips to reduce the thickness of the chips; plastically sealing the chips having undergone the thinning treatment to form a plastically sealed arrangement layer, and stacking at least two such plastically sealed arrangement layers on the substrate along plastic sealing direction; and punching the chips having undergone the thinning treatment to form first interconnection hole connecting the chips having undergone the thinning treatment to the substrate wiring structure, the chip in substrate, or the plastically sealed arrangement layer.

### TECHNICAL FIELD

The present disclosure relates to the field of microelectronic packaging, specifically to chip packaging, in particular to a chip packaging method and a chip packaging structure.

### BACKGROUND ART

As the physical limits of Moore's law are approached, the field of integrated circuits will face new innovations, which requires smaller chip sizes and higher performances. Currently, three-dimensional packaging is an effective method satisfying various standards and meeting the manufacturing requirements, and the three-dimensional packaging realizes interconnection of upper and lower layers through an interconnection hole technology. However, the multi-layer stacked semiconductor structure currently realized by three-dimensional packaging is not ideal for heat dissipation effect of the packaged chip due to factors such as thickness limitations of each layer, and therefore cannot satisfy the architectural need of more stacked layers.

### SUMMARY

In order to solve the technical problems known in the art, the present disclosure is intended to provide a chip packaging method and a chip packaging structure. For example, it can be achieved that after chips are attached on a substrate, only the thickness of each chip is selectively thinned without affecting other structures, thereby achieving better heat dissipation performance of the chips, enabling higher-density 3D interconnection of more stacked layers after the thinning, and lowering requirements to a punching device, which is thus beneficial to improvement of device performances.

In the following, a brief summary of the present disclosure will be given in order to provide a basic understanding of certain aspects of the present disclosure. It should be understood that this summary is not an exhaustive summary of the present disclosure. It is not intended to determine the key or important part of the present disclosure, nor is it intended to limit the scope of the present disclosure. Its purpose is merely to present some concepts in a simplified form as a prelude to the more detailed description that will be discussed later.

According to the contents of the present disclosure, a chip packaging method is provided, including: attaching at least two chips to one side of a substrate via an adhesive layer, wherein a device surface of the chip faces the substrate, and the substrate is provided therein with a substrate wiring structure and/or a chip; performing a thinning treatment on the at least two chips provided on one side of the substrate, wherein the thinning treatment includes etching only the chips so as to reduce the thickness of the chips; plastically sealing the chips having undergone the thinning treatment so as to form a plastically sealed arrangement layer, and stacking at least two plastically sealed arrangement layers on the substrate along a plastic sealing direction; and punching the chips having undergone the thinning treatment, to form a first interconnection hole connecting the chips having undergone the thinning treatment and the substrate wiring structure, the chip in the substrate, or the plastically sealed arrangement layer.

Optionally, a package wiring layer and an adhesive layer are sequentially formed between two adjacent plastically sealed arrangement layers in the at least two plastically sealed arrangement layers along a plastic sealing direction, or an insulation layer, a package wiring layer, and an adhesive layer are sequentially formed between two adjacent plastically sealed arrangement layers in the at least two plastically sealed arrangement layers along the plastic sealing direction.

Optionally, the substrate is provided therein with a chip, including: providing at least two chips at different positions in the substrate and at the same height or different heights in a thickness direction of the substrate.

Optionally, the punching the chips having undergone the thinning treatment, to form a first interconnection hole connecting the chips having undergone the thinning treatment and the substrate wiring structure, the chip in the substrate, or the plastically sealed arrangement layer includes: punching from the surface of the plastically sealed arrangement layer adjacent to the substrate, to form a first interconnection hole extending through the plastically sealed arrangement layer adjacent to the substrate and the adhesive layer and extending to the substrate so as to connect the chip in the substrate or the substrate wiring structure.

Optionally, the chip packaging method further includes: punching from a surface of the insulating layer, to form a second interconnection hole extending through the insulating layer to the plastically sealed arrangement layer so as to connect the chip in the plastically sealed arrangement layer.

Optionally, the chip packaging method further includes: punching from a surface of a plastically sealed arrangement layer that is not adjacent to the substrate, to form a third interconnection hole extending through the plastically sealed arrangement layer that is not adjacent to the substrate and the adhesive layer so as to connect the package wiring layer.

Optionally, the chip packaging method further includes: punching from a surface of a plastically sealed arrangement layer that is not adjacent to the substrate, to form a fourth interconnection hole sequentially extending through the plastically sealed arrangement layer that is not adjacent to the substrate, the adhesive layer, the package wiring layer, and the plastically sealed arrangement layer that is adjacent to the substrate, and extending to the substrate so as to connect the chip in the substrate.

Optionally, an aperture of each of the first interconnection hole, the second interconnection hole, the third interconnection hole and the fourth interconnection hole is smaller than a width of the chip.

Optionally, the thicknesses of the chips are the same or different.

Optionally, the thickness of the chips before being thinned is between 0 μm and 150 μm.

Optionally, the thickness of the chips after being thinned is between 0 μm and 20 μm.

Optionally, the thickness of the plastically sealed arrangement layer is greater than the thickness of the chips having undergone the thinning treatment.

Optionally, the etching the chips includes etching the chips with an acid liquid, an alkaline liquid, or a plasma gas.

Optionally, the thinning treatment includes thinning and polishing treatments.

Optionally, the substrate wiring structure is a pattern on silicon, glass, organic carrier plate, or a metallic insulated composite material.

Optionally, the substrate is a panel or a wafer made of silicon, silicon oxide, glass, silicon nitride, a composite material, or a plastic-sealed resin material.

Optionally, the adhesive layer is made of a semi-cured dry film, a liquid, or a metal.

Optionally, materials for making the plastically sealed arrangement layer include one selected from the group consisting of an insulating substance, polyimide, benzocyclobutene, parylene, an industrialized liquid crystal polymer, an epoxy resin, an oxide of silicon, a nitride of silicon, and an oxide of aluminum.

According to the contents of the present disclosure, a chip packaging structure is further provided, including: a substrate, wherein the substrate is provided therein with a substrate wiring structure and/or a chip; at least two plastically sealed arrangement layers, configured to be stacked along a plastic sealing direction on one side of the substrate, wherein each of the plastically sealed arrangement layers includes at least two chips, a device surface of the chip in the plastically sealed arrangement layer faces the substrate, the chips in the plastically sealed arrangement layer are configured to be attached to one side of the substrate via an adhesive layer and then subjected to a thinning treatment, wherein the thinning treatment includes etching only the chips so as to reduce the thickness of the chips; and a first interconnection hole, configured to connect the chips having undergone the thinning treatment to the substrate wiring structure, the chip in the substrate, or the plastically sealed arrangement layer.

Optionally, a package wiring layer and an adhesive layer are sequentially formed between two adjacent plastically sealed arrangement layers in the at least two plastically sealed arrangement layers along a plastic sealing direction, or an insulation layer, a package wiring layer, and an adhesive layer are sequentially formed between two adjacent plastically sealed arrangement layers in the at least two plastically sealed arrangement layers along the plastic sealing direction.

Optionally, the chip packaging structure further includes: at least two chips provided at different positions in the substrate and at the same height or different heights in a thickness direction of the substrate.

Optionally, the first interconnection hole is further configured to extend, from a surface of a plastically sealed arrangement layer adjacent to the substrate, through the plastically sealed arrangement layer adjacent to the substrate and the adhesive layer and to extend to the substrate so as to connect the chip in the substrate.

Optionally, the chip packaging structure further includes: a second interconnection hole, configured to extend, from a surface of the insulating layer, through the insulating layer to the plastically sealed arrangement layer so as to connect the chips in the plastically sealed arrangement layer.

Optionally, the chip packaging structure further includes: a third interconnection hole, configured to extend, from a surface of a plastically sealed arrangement layer that is not adjacent to the substrate, through the plastically sealed arrangement layer that is not adjacent to the substrate and the adhesive layer so as to connect the package wiring layer.

Optionally, the chip packaging structure further includes: a fourth interconnection hole, configured to extend, from a surface of a plastically sealed arrangement layer that is not adjacent to the substrate, through the plastically sealed arrangement layer that is not adjacent to the substrate, the adhesive layer, the package wiring layer, and the plastically sealed arrangement layer that is adjacent to the substrate in sequence, and to extend to the substrate so as to connect the chip in the substrate.

Optionally, an aperture of each of the first interconnection hole, the second interconnection hole, the third interconnection hole, and the fourth interconnection hole is smaller than a width of the chip.

Optionally, the thicknesses of the chips are the same or different.

Optionally, the thickness of the chips before being thinned is between 0 μm and 150 μm.

Optionally, the thickness of the chips after being thinned is between 0 μm and 20 μm.

Optionally, the thickness of the plastically sealed arrangement layer is greater than the thickness of the chips having undergone the thinning treatment.

Optionally, the etching the chips includes etching the chips with an acid liquid, an alkaline liquid, or a plasma gas.

Optionally, the thinning treatment includes thinning and polishing treatments.

Optionally, the substrate wiring structure is a pattern on silicon, glass, organic carrier plate, or a metallic insulated composite material.

Optionally, the substrate is a panel or a wafer made of silicon, silicon oxide, glass, silicon nitride, a composite material, or a plastic-sealed resin material.

Optionally, the adhesive layer is made of a semi-cured dry film, a liquid, or a metal.

Optionally, materials for making the plastically sealed arrangement layer include one selected from the group consisting of an insulating substance, polyimide, benzocyclobutene, parylene, an industrialized liquid crystal polymer, an epoxy resin, an oxide of silicon, a nitride of silicon, and an oxide of aluminum.

The solutions of the present disclosure can at least help to achieve one of the following effects: selectively thinning the chip surfaces, which avoids the process of using bonding equipment, and improves compatibility with other processes; rendering better heat dissipation performance of chip, higher density, and wiring architecture of more stacked layers, reducing photolithography, masking and other process steps, and reducing the punching depth so as to reduce the requirements to the punching device.

### BRIEF DESCRIPTION OF DRAWINGS

Specific contents of the present disclosure are described in the following with reference to the accompanying drawings, which will help to more easily understand the above and other objectives, features, and advantages of the present disclosure. The drawings are only to illustrate the principle of the present disclosure. In the drawings, it is unnecessary to draw sizes and relative positions of units according to scale. In the accompanying drawings:

FIG. 1 is a schematic flowchart of a chip packaging method according to an embodiment of the present disclosure;

FIGS. 2-23 show schematic sectional views of a chip according to an embodiment of the present disclosure; and

FIG. 24 shows a schematic sectional view of the chip according to an embodiment of the present disclosure.

### DETAILED DESCRIPTION OF EMBODIMENTS

Exemplary disclosures of the present disclosure will be described below in conjunction with the accompanying drawings. For the sake of clarity and conciseness, not all features that realize the present disclosure are described in the description. However, it should be appreciated that many decisions specific to the present disclosure may be made in the course of developing any contents for realizing the present disclosure, so as to achieve the developer's specific objectives, and such decisions may vary with differences of the present disclosure.

It is also to be noted herein that, in order to avoid obscuring the present disclosure with unnecessary details, only device structures closely related to the solution according to the present disclosure are shown in the accompanying drawings, and other details not closely related to the present disclosure are omitted.

It should be understood that the present disclosure is not merely limited to the described embodiments due to the following description made with reference to the accompanying drawings. In the present disclosure, features between different solutions may be replaced or borrowed, and one or more features may be omitted in one solution, where possible.

The drawings may be referred to in the following specific embodiments, and the drawings form a part of the present disclosure and illustrate exemplary embodiments. In addition, it should be understood that other embodiments may be utilized and structural and/or logical changes may be made without departing from the scope of the claimed subject matter. It should also be pointed out that directions and references (for example, up, down, top, bottom) are only used to help the description of the features in the drawings, while it is not intended to merely adopt the following specific embodiments in a restrictive sense.

As used in the specification and appended claims of the present disclosure, unless the context clearly dictates otherwise, the singular forms “a (an)”, “one” and “the” also include plural forms. It will also be understood that the term “and/or” as used herein refers to and includes any and all possible combinations of one or more of the associated listed items.

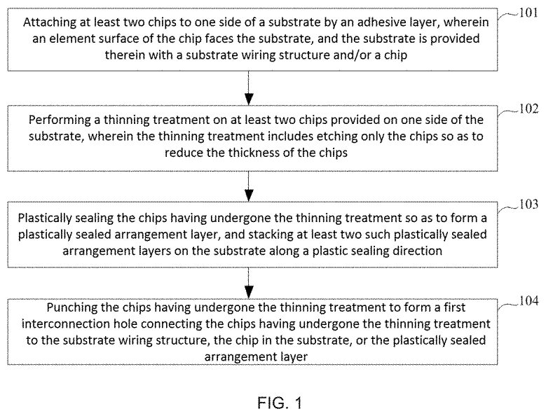

A chip packaging method according to an embodiment of the present disclosure is described with reference to FIG. 1. FIG. 1 shows a schematic flowchart of the chip packaging method according to an embodiment of the present disclosure.

As shown in FIG. 1, in the embodiment of the present disclosure, the chip packaging method includes:

step 101, attaching at least two chips to one side of a substrate by an adhesive layer, wherein a device surface of the chip faces the substrate, and the substrate is provided therein with a substrate wiring structure and/or a chip.

In an embodiment of the present disclosure, a material for packaging the substrate may be selected according to actual needs, and a specific material of the substrate is not limited. Optionally, the substrate may be a panel or a wafer made of silicon, silicon oxide, glass, silicon nitride, a composite material, a plastic-sealed resin and other materials, and may have a thickness of 0˜500 μm. Optionally, the substrate may be a bare chip not containing any circuit connection; optionally, the substrate may contain at least one or more chips for circuit connection; and optionally, the substrate wiring structure may be a pattern on silicon, glass, an organic carrier plate, or a metallic insulated composite material.

Optionally, the adhesive layer may be a semi-cured dry film, a liquid, or a metal, and after the attachment is completed, the bonding between the chip and the substrate may be enhanced through further operations such as curing, diffusion, and/or soldering.

Step 102, performing a thinning treatment on at least two chips provided on one side of the substrate, wherein the thinning treatment includes etching only the chips so as to reduce the thickness of the chips.

Here, etching the chips so as to reduce the thickness of the chips may be soaking and etching an entire device together so as to achieve etch-thinning after attaching/adhering the chips to the substrate, or preferably, a selective etching method is adopted: selectively etching only the chips so as to reduce the thickness of the chips without affecting other structures. Optionally, etching the chips includes etching the chips with an acidic liquid, an alkaline liquid, plasma and other gases. It may be understood that based on the thinning treatment of an embodiment of the present disclosure, the chip thickness can be reduced, and further the thickness of the entire chip packaging structure of the embodiment of the present disclosure can be reduced, so that the multi-layer stacked structure of the chips of the present disclosure can be realized. In addition, a punching depth is reduced due to the thinning of the chips, so that requirements to a punching device such as TSV punching device are reduced, thereby reducing the industrial cost of chip packaging and improving the production efficiency. Optionally, the thinning treatment includes thinning, polishing and other treatments.

Step 103, plastically sealing the chips having undergone the thinning treatment so as to form a plastically sealed arrangement layer, and stacking at least two such plastically sealed arrangement layers on the substrate along a plastic sealing direction.

Forming the plastically sealed arrangement layer here may be plastically sealing at least two chips, having undergone the thinning treatment, on a surface of the substrate so as to form the plastically sealed arrangement layer injection-molded and packaged. Optionally, the thickness of the plastically sealed arrangement layer is greater than the thickness of the chips having undergone the thinning treatment. Optionally, materials for making the plastically sealed arrangement layer may include: an insulating substance, polyimide, benzocyclobutene (BCB), parylene, an industrialized liquid crystal polymer (LCP), an epoxy resin, an oxide of silicon, a nitride of silicon, an oxide of aluminum, and the like.

Herein, stacking at least two such plastically sealed arrangement layers may be forming a plastically sealed arrangement layer on one side of the substrate, then, a second plastically sealed arrangement layer is continuously formed on the surface of this plastically sealed arrangement layer, in a manner similar to that of forming the first plastically sealed arrangement layer: at least two chips may be provided on an adhesive layer formed on the first plastically sealed arrangement layer, the at least two chips provided on the adhesive layer are subjected to a thinning treatment, then the at least two chips that have undergone the thinning treatment are plastically sealed on the adhesive layer so as to form the second plastically sealed arrangement layer, thus, stacking of two plastically sealed arrangement layers is realized. In this way, more plastically sealed arrangement layers can be stacked on the substrate.

Step 104, punching the chips having undergone the thinning treatment to form a first interconnection hole connecting the chips having undergone the thinning treatment to the substrate wiring structure, the chip in the substrate, or the plastically sealed arrangement layer.

Here, punching the chips having undergone the thinning treatment may be performed after the chips having undergone the thinning treatment are plastically sealed. Since the thickness of the plastically sealed arrangement layer should be larger than the chips having undergone the thinning treatment, the punching may be started first from the surface of the plastically sealed arrangement layer to the chip, then extending through the chip to extend to the wiring structure in the substrate, or the chip in the substrate, or the plastically sealed arrangement layer or other plastically sealed arrangement layers, to form the first interconnection hole, and the required interconnection hole can be easily drilled out because the thickness of the chips is reduced.

Optionally, a package wiring layer and an adhesive layer are sequentially formed between two adjacent plastically sealed arrangement layers in the at least two plastically sealed arrangement layers along a stacking direction, or an insulation layer, a package wiring layer, and an adhesive layer are sequentially formed between two adjacent plastically sealed arrangement layers in the at least two plastically sealed arrangement layers along the stacking direction.

In general, the adhesive layer needs to be made of an insulating material. It is unnecessary to form an insulating layer in cases where the adhesive layer is insulated, and the insulating layer herein may be provided in cases where the adhesive layer is not insulated. The function of the adhesive layer herein is similar to that of the chip in the plastically sealed arrangement layer closest to the substrate, and may be used for forming a plastically sealed arrangement layer thereon, and enabling the chip in the plastically sealed arrangement layer to be adhered thereto.

Optionally, the method further includes: providing at least two chips at different positions in the substrate and at the same or different heights in a thickness direction of the substrate. In other words, different chips may be provided at different spatial positions in the substrate. Optionally, different chips may be aligned according to the chips in the plastically sealed arrangement layer with respect to an upper layer of the substrate.

Optionally, the method further includes: punching from a surface of a plastically sealed arrangement layer adjacent to the substrate, to form a first interconnection hole extending through the plastically sealed arrangement layer adjacent to the substrate and the adhesive layer to the substrate so as to connect the chip in the substrate.

Optionally, the method further includes: punching from a surface of the insulating layer, to form a second interconnection hole extending through the insulating layer to the plastically sealed arrangement layer so as to connect the chip in the plastically sealed arrangement layer.

Optionally, the method further includes: punching from a surface of a plastically sealed arrangement layer that is not adjacent to the substrate, to form a third interconnection hole extending through the plastically sealed arrangement layer that is not adjacent to the substrate and the adhesive layer so as to connect the package wiring layer.

Optionally, the method further includes: punching from a surface of a plastically sealed arrangement layer that is not adjacent to the substrate, to form a fourth interconnection hole sequentially extending through the plastically sealed arrangement layer that is not adjacent to the substrate, the adhesive layer, the package wiring layer, and the plastically sealed arrangement layer that is adjacent to the substrate, to the substrate so as to connect the chip in the substrate.

Optionally, an aperture of each of the first interconnection hole, the second interconnection hole, the third interconnection hole, and the fourth interconnection hole is smaller than a width of the chip.

Optionally, the thicknesses of the chips are the same or different.

Optionally, the thickness of the chips before being thinned is between 0 μm and 150 μm.

Optionally, the thickness of the chips after being thinned is between 0 μm and 20 μm. Herein, after the chips are adhered to the adhesive layer/substrate, the thickness of the chips may be selectively specially thinned to between 0 μm and 20 μm, so as to achieve technical advantages.

Optionally, the adhesive layer may be made of an acid-resistant and/or alkali-resistant material. Optionally, the adhesive layer may be plated with a protective layer to resist etching.

Optionally, the thinning treatment includes wet thinning.

In the chip packaging method provided in an embodiment of the present disclosure, a multi-layer stacked structure can be realized as the chips were subjected to the thinning treatment, so that the entire chip has a reduced thickness and thus has better heat dissipation performance. The packaging manner thereof is also simplified, the use of bonding equipment and chemical mechanical polish (CMP) is reduced, and the punching depth is reduced, thus the requirements to the punching device are reduced.

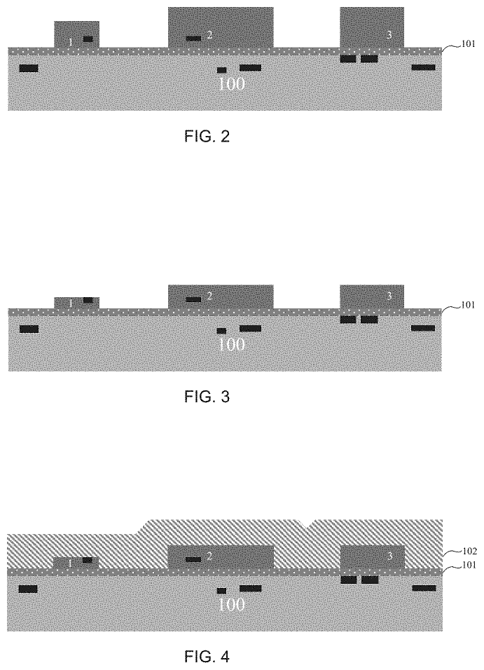

For a better understanding of the chip packaging method provided in the embodiment of the present disclosure, the chip packaging method with two plastically sealed arrangement layers according to the embodiment of the present disclosure is taken as an example below, to illustrate a chip packaging process according to the present embodiment in detail, in combination with FIG. 2 to FIG. 23.

Step S1, attaching a chip on the substrate.

As shown in FIG. 2, the substrate 100 may be silicon, silicon oxide, glass, silicon nitride, a composite material, a plastic-sealed resin or other materials, with a thickness of 0˜500 μm; 101 may be a non-conductive first adhesive layer, covering the substrate; a chip 1, a chip 2, and a chip 3 are included in the figure, herein three chips are illustrated, and any other number is also possible, and the chip 1, the chip 2, and the chip 3 may be a chip with a device or a bare chip.

Step S2, etch-thinning the chips.

As shown in FIG. 3, compared with the chip shown in FIG. 2, the thickness of the chips is reduced. Specifically, a selective etching manner may be selected, only the chip 1, the chip 2, and the chip 3 are etched, and the first adhesive layer 101 is not etched. A predetermined etching thickness may be achieved by controlling an etching rate, and the etching may be controlled by controlling a selection ratio of surface etching of the first adhesive layer to the chips. Moreover, a protective film (not shown in FIG. 3) may be plated by chemical vapor deposition (CVD), atomic layer deposition (ALD), or the like before etching to protect a side wall and the adhesive layer.

Step S3, injection molding, packaging molding, and leveling.

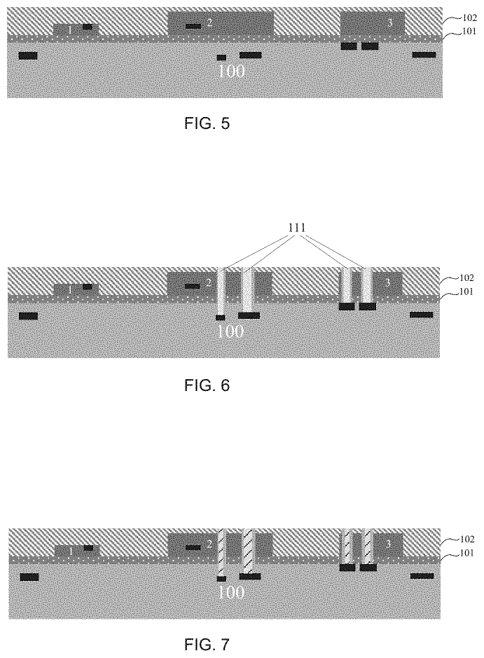

As shown in FIG. 4, a first plastically sealed arrangement layer 102 is formed on the adhesive layer, the first plastically sealed arrangement layer 102 wraps the chips therein, and is ground after being cured, but the chips are not eroded, thus forming a packaging structure as shown in FIG. 5.

Step S4, engraving holes (punching) in a plastic-sealed surface and the chips.

As shown in FIG. 6, engraving holes in the chip 2, the chip 3, and the plastic-sealed surface is illustrated, wherein the hole engraving may adopt a laser etching method or a deep anti-ion etching method, the thickness of the chip 2 and the chip 3 is less than 200 μm, a patterned photoresist layer (not shown in the drawing) is formed on the layer 102, and then deep etching is performed. The punching depth may pass through the first plastically sealed arrangement layer 102 and the first adhesive layer 101 to reach the substrate 100, so as to connect the chip in the substrate 100. Four holes 111 punched as shown in FIG. 6 correspond to the first interconnection holes as described above.

The first interconnection hole, extending through the plastically sealed arrangement layer adjacent to the substrate and the adhesive layer to the substrate so as to connect the chip in the substrate, is formed by punching from the surface of the plastically sealed arrangement layer adjacent to the substrate.

Step S5, depositing an insulator (not shown in the drawing) on an inner wall of the hole.

Step S6, filling a conductive material and grinding a surface after depositing an insulator and plating a seed layer on the inner wall of the hole.

As shown in FIG. 7, a device in the substrate 100 is connected, and the photoresist layer is finally removed.

Step S7, depositing an insulating layer 103 on the surface of the first plastically sealed arrangement layer 102.

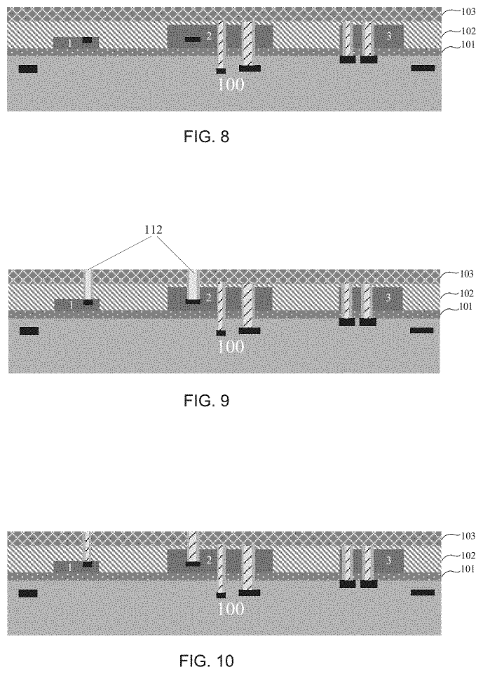

As shown in FIG. 8, a spin coating method may be adopted, or vacuum film covering also may be performed.

Step S8, engraving holes in a plastic-sealed surface and the chips.

As shown in FIG. 9, holes are engraved in the insulating layer 103, the chip 1, and the chip 2, to form the second interconnection holes 112 extending through the insulating layer 103 to the first plastically sealed arrangement layer 102 so as to connect the chips in the plastically sealed arrangement layer 102.

Step S9, filling a conductive material and grinding a surface after depositing an insulator and plating a seed layer on the inner wall of the hole, as shown in FIG. 10.

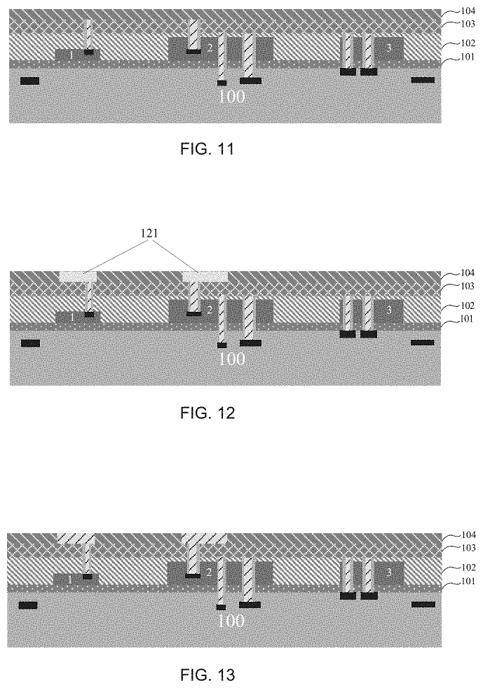

Step S10, depositing a first package wiring layer 104 on the surface of the insulating layer 103, and etching a first RDL trunking 121 in the layer 104, as shown in FIG. 11 and FIG. 12.

Step S11, filling a conductive material in the first RDL trunking 121, as shown in FIG. 13.

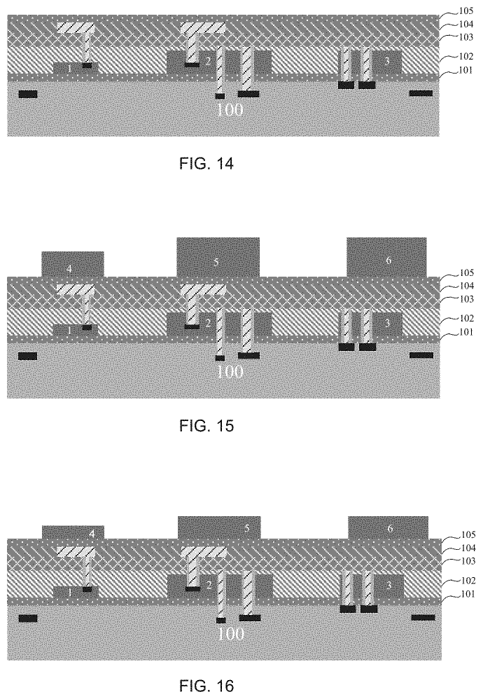

Step S12, attaching a second adhesive layer 105 to the surface of the first package wiring layer 104, wherein the second adhesive layer 105 may be made of an insulating material, as shown in FIG. 14.

Step S13, adhering a chip 4, a chip 5, and a chip 6 on the second adhesive layer 105, as shown in FIG. 15.

Step S14, etch-thinning the chip 4, the chip 5, and the chip 6, as shown in FIG. 16.

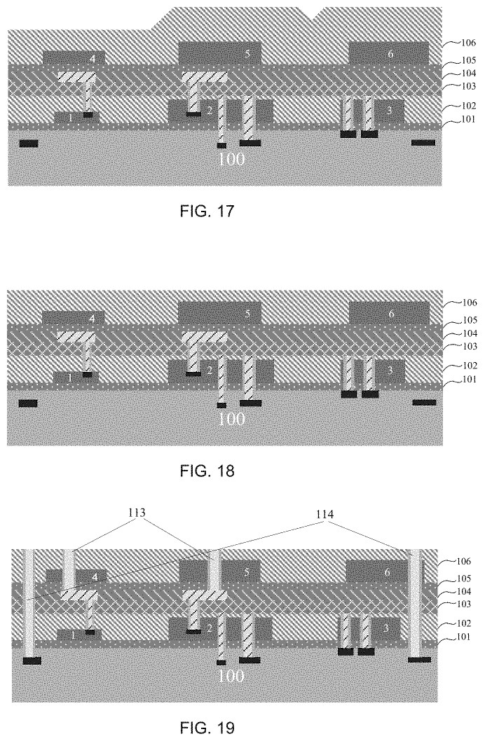

Step S15, injection molding and packaging molding, thus forming the second plastically sealed arrangement layer 106 as shown in FIG. 17.

Step S16, leveling, as shown in FIG. 18.

Step S17, punching holes 113, 114.

As shown in FIG. 19, the third interconnection holes 113, extending through the second plastically sealed arrangement layer 106 and the second adhesive layer 105 to the first RDL trunking 121 in the first package wiring layer 104, are formed, and the fourth interconnection holes 114, extending through the second plastically sealed arrangement layer 106, the second adhesive layer 105, the first package wiring layer 104, the insulating layer 103, the first plastically sealed arrangement layer 102, and the first adhesive layer 101 in sequence to the substrate 100 so as to connect the chips in the substrate 100, are formed.

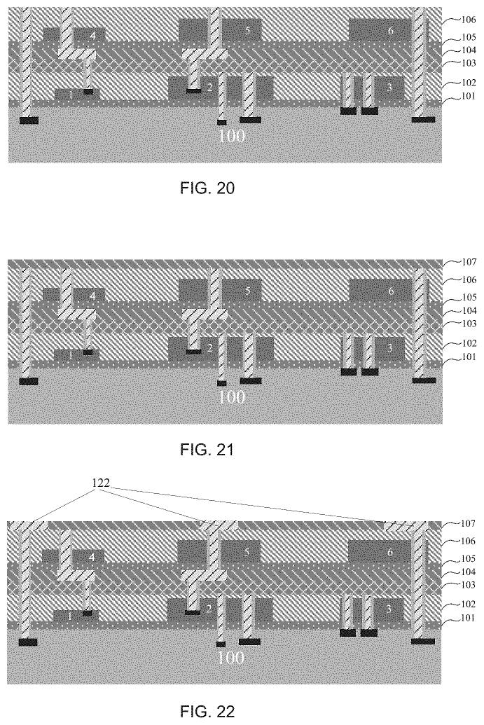

Step S18, filling the holes, as shown in FIG. 20, wherein filling the holes may be specifically implemented with reference to the foregoing hole filling operation.

Step S19, depositing a second package wiring layer 107 on the surface as shown in FIG. 21.

Step S20, etching a second RDL trunking 122, and filling the second RDL trunking with a conductive material, as shown in FIG. 22.

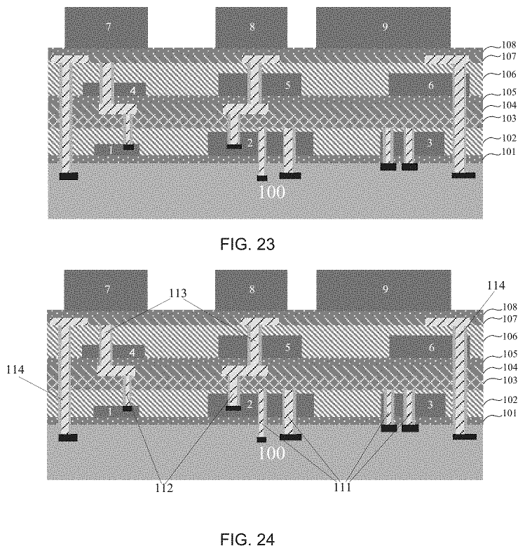

Step S21, attaching a third adhesive layer 108 to a surface of the second package wiring layer 107, wherein the third adhesive layer 108 may be made of an insulating material, as shown in FIG. 23.

Step S22, adhering a chip 7, a chip 8, and a chip 9 on the third adhesive layer 108, as shown in FIG. 23.

Optionally, the layers are continuously stacked along the thickness direction of the substrate 100 according to steps S1-S22, to form the chip packaging structure according to the present embodiment.

A chip according to an embodiment of the present disclosure is described with reference to FIG. 24. FIG. 24 illustrates a schematic sectional view of a chip having two plastically sealed arrangement layers according to an embodiment of the present disclosure.

The chip disclosed in an embodiment of the present disclosure includes a substrate, and the substrate is provided therein with a substrate wiring structure and/or a chip; at least two plastically sealed arrangement layers, configured to be stacked along a plastic sealing direction on one side of the substrate, wherein each of the plastically sealed arrangement layers includes at least two chips, a device surface of the chip in the plastically sealed arrangement layer faces the substrate, the chips in the plastically sealed arrangement layer are configured to be attached to one side of the substrate by an adhesive layer and then subjected to a thinning treatment, wherein the thinning treatment includes etching only the chips so as to reduce the thickness of the chips; and a first interconnection hole, configured to connect the chips having undergone the thinning treatment to the substrate wiring structure, the chip in the substrate, or the plastically sealed arrangement layer.

Taking a chip having two plastic package arrangement layers as illustrated in FIG. 24 as an example, the chip includes at least two plastically sealed arrangement layers: a first plastically sealed arrangement layer 102 and a second plastically sealed arrangement layer 106, stacked on one side of the substrate 100 along a thickness direction, the first plastically sealed arrangement layer 102 or the second plastically sealed arrangement layer 106 includes at least two chips, wherein the at least two chips are configured to be subjected to a thinning treatment after being provided on one side of the substrate 100 or the first adhesive layer 101/the second adhesive layer 105/the third adhesive layer 108, and wherein the thinning treatment includes etching only the chips so as to reduce the thickness of the chips.

Optionally, configuring the at least two chips to be provided on one side of the substrate includes: adhering the at least two chips to an adhesive layer formed on one side of the substrate. Taking FIG. 24 as an example, configuring the at least two chips to be provided on one side of the substrate 100 includes: adhering the at least two chips to the first adhesive layer 101 formed on one side of the substrate 100.

Optionally, a package wiring layer and an adhesive layer are sequentially formed between two adjacent plastically sealed arrangement layers in the at least two plastically sealed arrangement layers along a stacking direction, or an insulation layer, a package wiring layer, and an adhesive layer are sequentially formed between two adjacent plastically sealed arrangement layers in the at least two plastically sealed arrangement layers along the stacking direction. In general, the adhesive layer needs to be made of an insulating material. It is unnecessary to provide an insulating layer in cases where the adhesive layer is insulated, and the insulating layer herein may be provided in cases where the adhesive layer is not insulated. The function of the adhesive layer herein is similar to that of the chip in the plastically sealed arrangement layer closest to the substrate, and may be used for forming a plastically sealed arrangement layer thereon, and enabling the chip in the plastically sealed arrangement layer to be adhered thereto.

Taking FIG. 24 as an example, an insulating layer 103, a first package wiring layer, and a second adhesive layer 105 are sequentially formed between the first plastically sealed arrangement layer 102 and the second plastically sealed arrangement layer 106 along a stacking direction.

Optionally, the chip in the embodiment of the present disclosure further includes: at least two chips provided at different positions in the substrate and located at the same or different heights in a thickness direction of the substrate.

Optionally, the chip in the embodiment of the present disclosure further includes:

a first interconnection hole, configured to extend, from a surface of a plastically sealed arrangement layer adjacent to the substrate, through the plastically sealed arrangement layer adjacent to the substrate and the adhesive layer to the substrate so as to connect the chip in the substrate. Taking FIG. 24 as an example, the first interconnection hole 111 is configured to extend, from the surface of the first plastically sealed arrangement layer 102 adjacent to the substrate 100, through the first plastically sealed arrangement layer 102 adjacent to the substrate 100 and the first adhesive layer 101 to the substrate 100 so as to connect the chip in the substrate 100.

Optionally, the chip in the embodiment of the present disclosure further includes:

a second interconnection hole, configured to extend, from a surface of the insulating layer, through the insulating layer to the plastically sealed arrangement layer so as to connect the chips in the plastically sealed arrangement layer. Taking FIG. 24 as an example, the second interconnection hole 112 is configured to extend, from a surface of the insulating layer 103, through the insulating layer 103 to the first plastically sealed arrangement layer 102 so as to connect the chips in the plastically sealed arrangement layer 102.

Optionally, the chip in the embodiment of the present disclosure further includes:

a third interconnection hole, configured to extend, from a surface of a plastically sealed arrangement layer that is not adjacent to the substrate, through the plastically sealed arrangement layer that is not adjacent to the substrate and the adhesive layer so as to connect the package wiring layer. Taking FIG. 24 as an example, the third interconnection hole 113 is configured to extend, from a surface of the second plastically sealed arrangement layer 106, through the second plastically sealed arrangement layer 106 and the second adhesive layer 105 so as to connect the first package wiring layer 104.

Optionally, the chip in the embodiment of the present disclosure further includes:

a fourth interconnection hole, configured to extend, from a surface of a plastically sealed arrangement layer that is not adjacent to the substrate, through the plastically sealed arrangement layer that is not adjacent to the substrate, the adhesive layer, the package wiring layer, and the plastically sealed arrangement layer that is adjacent to the substrate in sequence, to the substrate so as to connect the chip in the substrate. Taking FIG. 24 as an example, the fourth interconnection hole is configured to extend, from a surface of a second plastically sealed arrangement layer 106, through the second plastically sealed arrangement layer 106, the second adhesive layer 105, the first package wiring layer 104, and the first plastically sealed arrangement layer 102 in sequence to the substrate 100, so as to connect the chip in the substrate 100.

Optionally, an aperture of each of the first interconnection hole, the second interconnection hole, the third interconnection hole, and the fourth interconnection hole is smaller than a width of the chip.

Optionally, the thicknesses of the chips are the same or different.

Optionally, the thickness of the chips before being thinned is between 0 μm and 150 μm.

Optionally, the thickness of the chips after being thinned is between 0 μm and 20 μm.

Optionally, the adhesive layer is made of an insulating material.

Optionally, a redistribution layer slot (RDL slot) is etched in the insulating layer, wherein the redistribution layer slot is filled with a conductive material.

Optionally, the first interconnection hole, the second interconnection hole, the third interconnection hole, and/or the fourth interconnection hole is filled with a conductive material.

Optionally, the thickness of the plastically sealed arrangement layer is greater than the thickness of the chips having undergone the thinning treatment.

Optionally, the etching the chips includes etching the chips with an acid liquid, an alkaline liquid, or a plasma gas.

Optionally, the thinning treatment includes thinning and polishing treatments.

Optionally, the substrate wiring structure is a pattern on silicon, glass, organic carrier plate, or a metallic insulated composite material.

Optionally, the substrate is a panel or a wafer made of silicon, silicon oxide, glass, silicon nitride, a composite material, or a plastic-sealed resin material.

Optionally, the adhesive layer is made of a semi-cured dry film, a liquid, or a metal.

Optionally, materials for making the plastically sealed arrangement layer include one selected from the group consisting of an insulating substance, polyimide, benzocyclobutene, parylene, an industrialized liquid crystal polymer, an epoxy resin, an oxide of silicon, a nitride of silicon, and an oxide of aluminum.

It should be noted that FIG. 24 merely schematically illustrates the chip packaging structure having two plastically sealed arrangement layers, and in practical applications, the embodiments of the present disclosure may have a stacked structure with more layers, and a specific configuration thereof may be formed by stacking more layers based on the packaging structure of two plastically sealed arrangement layers illustrated in FIG. 24, and a specific packaging method thereof may be understood with reference to the above-described chip packaging method.

For the chip provided in the embodiments of the present disclosure, as the chips having undergone the thinning treatment are contained, the multi-layer stacked structure can be realized, so that the entire chip has a reduced thickness and thus has better heat dissipation performance. The packaging manner thereof is also simplified, the use of bonding equipment and chemical mechanical polish (CMP) is reduced, and the punching depth is reduced, thus the requirements to the punching device are reduced.

The present disclosure has been described in connection with the specific embodiments above, but it should be understood by a person skilled in the art that all of these descriptions are illustrative, and not intended to limit the scope of protection of the present disclosure. A person skilled in the art could make various modifications and changes to the present disclosure in accordance with the spirit and principles of the present disclosure, and these modifications and changes are also within the scope of the present disclosure.

### INDUSTRIAL APPLICABILITY

The embodiments of the disclosure provide the chip packaging structure and the chip packaging method. The multi-layer stacked structure can be realized as the chips in the embodiments of the present disclosure are subjected to the thinning treatment. The chip packaging method provided in the embodiment of the present disclosure can solve the problem that grinding with the known chemical and mechanical methods and wiring of a multi-layer metal wire are getting more and more difficult. The chip thinning realized can improve the compatibility with other processes, so that the entire chip has a reduced thickness and thus has better heat dissipation performance; the punching depth is reduced, thus the requirements to the punching process are reduced, and the packaging method is quicker, so that the productivity is improved; a large number of technical difficulties of the silicon interconnection hole technology may be solved, such as low productivity, high processing temperature, low density of the interconnection hole that can be realized, easy fragmentation, influence on silicon characteristics, high cost, and no bending. The thinning of the chips has great benefits to fan-out and 3D integrated packaging, can ensure the flexibility and high performance of the system, and improves the reliability of the whole system.

1-36. (canceled)

37. A chip packaging structure, comprising:
a substrate, wherein the substrate is provided therein with a substrate wiring structure and/or a chip;
at least two plastically sealed arrangement layers, configured to be stacked along a plastic sealing direction on one side of the substrate, wherein each of the plastically sealed arrangement layers comprises at least two chips, device surfaces of the chips in the plastically sealed arrangement layer face the substrate, the chips in the plastically sealed arrangement layer are configured to be attached to one side of the substrate by an adhesive layer and then subjected to a thinning treatment, wherein the thinning treatment comprises etching only the chips so as to reduce thicknesses of the chips; and
a first interconnection hole, configured to connect the chips having undergone the thinning treatment to the substrate wiring structure, the chip in the substrate or the plastically sealed arrangement layer.

38. The chip packaging structure according to claim 37, wherein a package wiring layer and the adhesive layer are sequentially formed between two adjacent plastically sealed arrangement layers in the at least two plastically sealed arrangement layers along the plastic sealing direction, or an insulation layer, the package wiring layer and the adhesive layer are sequentially formed between two adjacent plastically sealed arrangement layers in the at least two plastically sealed arrangement layers along the plastic sealing direction.

39. The chip packaging structure according to claim 37, further comprising: at least two chips provided at different positions in the substrate and at the same height or different heights in a thickness direction of the substrate.

40. The chip packaging structure according to claim 38, wherein the first interconnection hole is further configured to extend, from a surface of a plastically sealed arrangement layer adjacent to the substrate, through the plastically sealed arrangement layer adjacent to the substrate and the adhesive layer, and to extend to the substrate, so as to connect the chip in the substrate.

41. The chip packaging structure according to claim 38, further comprising:
a second interconnection hole, configured to extend, from a surface of the insulating layer, through the insulating layer to the plastically sealed arrangement layer so as to connect the chips in the plastically sealed arrangement layer.

42. The chip packaging structure according to claim 38, further comprising:
a third interconnection hole, configured to extend, from a surface of a plastically sealed arrangement layer that is not adjacent to the substrate, through the plastically sealed arrangement layer that is not adjacent to the substrate and the adhesive layer so as to connect the package wiring layer.

43. The chip packaging structure according to claim 38, further comprising:
a fourth interconnection hole, configured to extend, from a surface of a plastically sealed arrangement layer that is not adjacent to the substrate, through the plastically sealed arrangement layer that is not adjacent to the substrate, the adhesive layer, the package wiring layer and a plastically sealed arrangement layer that is adjacent to the substrate in sequence, and to extend to the substrate, so as to connect the chip in the substrate.

44. The chip packaging structure according to claim 43, wherein an aperture of each of the first interconnection hole, the second interconnection hole, the third interconnection hole and the fourth interconnection hole is smaller than widths of the chips.

45. The chip packaging structure according to claim 37, wherein the thicknesses of the chips are the same or different.

46. The chip packaging structure according to claim 37, wherein thicknesses of the chips before being thinned are between 20 μm and 150 μm.

47. The chip packaging structure according to claim 37, wherein a material for forming the plastically sealed arrangement layer comprises one selected from the group consisting of an insulating substance, polyimide, benzocyclobutene, parylene, an industrialized liquid crystal polymer, an epoxy resin, an oxide of silicon, a nitride of silicon and an oxide of aluminum.

48. A chip packaging method, comprising:
attaching at least two chips to one side of a substrate by an adhesive layer, wherein device surfaces of the chips face the substrate, and the substrate is provided therein with a substrate wiring structure and/or a chip;
performing a thinning treatment on the at least two chips provided on one side of the substrate, wherein the thinning treatment comprises etching only the chips so as to reduce thicknesses of the chips;
plastically sealing the chips having undergone the thinning treatment so as to form a plastically sealed arrangement layer, and stacking at least two plastically sealed arrangement layers on the substrate along a plastic sealing direction; and
punching the chips having undergone the thinning treatment so as to form a first interconnection hole connecting the chips having undergone the thinning treatment to the substrate wiring structure, the chip in the substrate or the plastically sealed arrangement layer.

49. The chip packaging method according to claim 48, wherein the substrate is provided therein with the chip, the method comprising:
providing at least two chips at different positions in the substrate and at the same height or different heights in a thickness direction of the substrate.

50. The chip packaging method according to claim 49, wherein the punching the chips having undergone the thinning treatment so as to form a first interconnection hole connecting the chips having undergone the thinning treatment to the substrate wiring structure, the chip in the substrate or the plastically sealed arrangement layer comprises:
punching from a surface of a plastically sealed arrangement layer adjacent to the substrate, so as to form a first interconnection hole extending through the plastically sealed arrangement layer adjacent to the substrate and the adhesive layer, and extending to the substrate, so as to connect the chip in the substrate or the substrate wiring structure.

51. The chip packaging method according to claim 49, further comprising:
punching from a surface of the insulating layer, so as to form a second interconnection hole extending through the insulating layer to the plastically sealed arrangement layer so as to connect the chips in the plastically sealed arrangement layer.

52. The chip packaging method according to claim 49, further comprising:
punching from a surface of a plastically sealed arrangement layer that is not adjacent to the substrate, so as to form a third interconnection hole extending through the plastically sealed arrangement layer that is not adjacent to the substrate and the adhesive layer so as to connect the package wiring layer.

53. The chip packaging method according to claim 49, further comprising:
punching from a surface of a plastically sealed arrangement layer that is not adjacent to the substrate, so as to form a fourth interconnection hole sequentially extending through the plastically sealed arrangement layer that is not adjacent to the substrate, the adhesive layer, the package wiring layer and a plastically sealed arrangement layer that is adjacent to the substrate, and extending to the substrate, so as to connect the chip in the substrate.

54. The chip packaging method according to claim 48, wherein the etching the chips comprises etching the chips by using an acid liquid, an alkaline liquid or a plasma gas and the thinning treatment comprises thinning and polishing treatments.

55. The chip packaging method according to claim 48, wherein the substrate is a panel or a wafer made of silicon, silicon oxide, glass, silicon nitride, a composite material or a plastic-sealed resin material.

56. The chip packaging method according to claim 48, wherein the adhesive layer is made of a semi-cured dry film, a liquid or a metal.
